(19) United States
(12) Patent Application Publication
(10) Pub. No.: US 2022/0399402 A1
(43) Pub. Date: Dec. 15, 2022

(54) CARBON NANOTUBE (CNT) MEMORY CELL ELEMENT AND METHODS OF CONSTRUCTION

(71) Applicant: Microchip Technology Incorporated, Chandler, AZ (US)

(72) Inventor: Yaojian Leng, Vancouver, WA (US)

(73) Assignee: Microchip Technology Incorporated, Chandler, AZ (US)

(21) Appl. No.: 17/409,940

(22) Filed: Aug. 24, 2021

Related U.S. Application Data
(60) Provisional application No. 63/208,928, filed on Jun. 9, 2021.

(51) Int. Cl. H01L 27/28; G11C 13/00; H01L 51/10; H01L 51/05

(52) U.S. Cl. CPC H01L 27/286; G11C 13/0014; H01L 51/102; H01L 51/0591; H01L 51/0595; G11C 2213/16

(57) ABSTRACT

Carbon nanotube (CNT) memory cell elements and methods of forming CNT memory cell elements are provided. A CNT memory cell may comprise a CNT memory cell element, e.g., in combination with a transistor. A CNT memory cell element may include a metal/CNT layer/metal (M/CNT/M) structure formed between adjacent metal interconnect layers or between a silicided active layer (e.g., including MOSFET devices) and a metal interconnect layer. The M/CNT/M structure may be formed by a process including forming a tub opening in a dielectric region, forming a cup-shaped bottom electrode in the tub opening, forming a cup-shaped CNT layer in an interior opening defined by the cup-shaped bottom electrode, and forming a top electrode in an interior opening defined by the cup-shaped CNT layer.

### RELATED APPLICATION

This application claims priority to commonly owned U.S. Provisional Patent Application No. 63/208,928 filed Jun. 9, 2021, the entire contents of which are hereby incorporated by reference for all purposes.

### TECHNICAL FIELD

The present disclosure relates to non-volatile memory (NVM), and more particularly to carbon nanotube (CNT) memory cell elements and methods of construction.

### BACKGROUND

Non-volatile memory (NVM) refers to memory that can retain data without an external power supply. NVM is useful for many applications, for example as a microcontroller component. In contrast, static random access memory (SRAM), typically composed of six transistors, needs external power to retain data. Similarly, dynamic random access memory (DRAM), typically including one transistor and one capacitor, also needs external power to retain and refresh data.

Currently, the most common form of NVM is flash memory, which comprises floating-gate based memory cells. NOR type flash memory is typically used for storing code, while NAND type flash memory is typically used for storing data. However, flash memory has various limitations and drawbacks. For example, it is difficult to continue to reduce the critical dimensions of flash memory. In addition, flash memory often requires high voltage (typically about 20V) for programming and erasing. Further, addition of flash memory cells to the typical CMOS process flow as embedded memory requires several additional photomask layers, for example, 5 or more mask layers. This significantly increases the cost of flash memory in embedded applications.

Thus, other types of NVM memory have been developed in recent years, including memory employing a carbon nanotube, referred to as carbon nanotube (CNT) memory. A carbon nanotube (CNT) is a tube made of carbon atoms with tiny diameter, typically of 1-100 nanometers. For a structure including a network of disordered (e.g., crossed) CNTs on a flat surface, nearby CNTs may be touching or slightly separated from each other in a direction normal to the substrate, as a function of Van der Waal's interactions between the various CNTs. For example, when the CNT network is charged in a manner that causes nearby CNTs to touch each other, the CNT network may exhibit a low resistance state, for example on the order of 100 kΩ In contrast, when the CNT network is charged in a manner that causes nearby CNTs to separate from each other, the CNT network may exhibit a high resistance state, for example on the order of 1 MΩ.

CNT memory cells, e.g., nano-RAM (NRAM) cells, utilize the phenomena discussed above, e.g., by selectively biasing each cell to switch a CNT memory cell element in the respective CNT memory cell between low resistance and high resistance states. CNT memory cells typically can be constructed with a 1T1C (one transistor, one capacitor) configuration including a transistor (e.g., a metal—oxide—semiconductor field-effect transistor, or MOSFET) and a CNT memory cell element having a structure of a capacitor but functioning as a switch between a high resistance state and a low resistance state. A CNT memory cell element is thus commonly referred to alternately as a capacitor or as a switch.

FIGS. 1A and 1B illustrates the general operating principle of an example CNT memory cell. FIG. 1A shows a circuit diagram of the example CNT memory cell including a transistor (e.g., MOSFET) and a CNT memory cell element, and FIG. 1B shows a structural cross-section of the CNT memory cell element. As shown in FIG. 1B, the CNT memory cell element includes a CNT region (labelled “CNT”) formed between a bottom electrode (e.g., tungsten) connected to a bottom metal layer Mₓ and a top electrode (e.g., tungsten) connected to a top metal layer Mₓ₊₁. To set (program) the CNT memory cell, a voltage (for example, 3V) is applied to the top electrode of the CNT memory cell element through the source line (SL), with the bottom electrode of the CNT memory cell element held at 0V by applying 0V to the bit line (BL), and activating the transistor, which transistor has a first terminal connected to the BL, a second terminal connected to the bottom electrode, and a gate terminal connected to a word line. This biasing causes CNTs in the CNT region to pull away from the bottom electrode, which electrically opens at least some conductive pathways between the top and bottom electrodes through the CNT region, thereby creating a high resistance state for the CNT memory cell element. To reset (erase) the CNT memory cell, a voltage (for example, 2.5V) is applied to the BL, and the transistor is activated, thereby coupling the BL voltage to the bottom electrode of the CNT memory cell element, while the SL connected to the top electrode of the CNT memory cell element is held at 0V. This biasing pulls the CNTs in the CNT region down toward the bottom electrode, closing many conductive pathways between the top and bottom electrodes through the CNT region, thereby creating a low resistance state for the CNT memory cell element.

CNT memory cells may provide various advantages, for example lower power consumption, greater circuit density, faster speed of operation, greater reliability due to the absence of tunneling through oxide, and/or immunity to ionizing radiation than flash memory cells.

However, CNT memory cells typically have various drawbacks or disadvantages. For example, some CNT memory cells require at least one added mask layer, as compared with the relevant background IC fabrication process.

As another example, construction of CNT memory cells may involve a stack etch that may be difficult to ash. Both photoresist and CNT are carbon based. A post-etch resist removal process, referred to as an ash process, thus has a very small process margin. For example, too little ash may leave resist remaining on the wafer, which may create defects and reduce device yield or reliability, while too much ash may damage or destroy the CNT structure. During a semiconductor manufacturing process, the critical dimension (CD) or overlay may be out of specification in the patterning step, and the photo resist may need to be completely removed to deposit and pattern a new photo resist layer to bring the CD and overlay within the manufacturing specification. This photo rework process may destroy the CNT structure.

There is a need for CNT memory cell and methods of constructing a CNT memory cell that reduce or eliminate any one or more of the drawbacks and challenges discussed above. For example, there is a need to build CNT memory cells at lower cost and with improved manufacturing processes, e.g., by reducing or eliminating added mask layers.

### SUMMARY

The present disclosure provides carbon nanotube (CNT) memory cell elements and methods of forming CNT memory cell elements. A CNT memory cell may comprise a CNT memory cell element may as a component thereof, e.g., in combination with a transistor, as discussed herein. A CNT memory cell element may include a metal/CNT layer/metal (M/CNT/M) structure formed between adjacent metal interconnect layers or between an active layer (e.g., including MOSFET devices) and a metal interconnect layer, e.g., metal-1 layer. The M/CNT/M structure of the CNT memory cell element may be formed by a process including forming a tub opening in a dielectric region, forming a cup-shaped bottom electrode in the tub opening, forming a cup-shaped CNT layer in an interior opening defined by the cup-shaped bottom electrode, and forming a top electrode in an interior opening defined by the cup-shaped CNT layer. In some examples, the cup-shaped bottom electrode may be formed concurrently with interconnect vias, e.g., by deposition of tungsten or other conformal metal. In some example, the CNT memory cell element may be formed without adding any photomask processes to a background integrated circuit fabrication process, e.g., a typical CMOS fabrication process.

One aspect provides a method of forming an integrated circuit structure including a CNT memory cell element, e.g., for use in a CNT memory cell. The method includes forming a tub opening in a dielectric region, forming a cup-shaped bottom electrode in the tub opening, forming a cup-shaped CNT layer in an interior opening defined by the cup-shaped bottom electrode, forming a top electrode in an interior opening defined by the cup-shaped CNT layer, and forming an upper metal layer over the dielectric region, the upper metal layer including a top electrode contact in contact with the top electrode. The cup-shaped bottom electrode, the cup-shaped CNT layer, and the top electrode define the CNT memory cell element.

In some examples, the CNT memory cell element is formed by a damascene process. Further, in some examples, the CNT memory cell element is formed without adding any photomask processes to a background integrated circuit fabrication process.

In some examples, the cup-shaped bottom electrode, the cup-shaped carbon nanotube layer, and the top electrode are formed in the tub opening in the dielectric region.

In some examples, before forming the upper metal layer over the dielectric region, a top surface of the CNT memory cell element is planarized, and a dielectric barrier layer is deposited to cover the planarized top surface of the CNT memory cell element. In one example, forming the upper metal layer over the dielectric region comprises etching an upper dielectric layer to form a top electrode contact opening for forming the top electrode contact, and the dielectric barrier layer acts as an etch stop during the etch.

In some examples, the method includes concurrently forming the tub opening and a via opening in the dielectric region, and depositing a conformal metal to concurrently form the cup-shaped bottom electrode in the tub opening and a via in the via opening. In some examples, forming the upper metal layer over the dielectric region comprises concurrently forming the top electrode contact in contact with the top electrode and an upper interconnect element in contact with the via. The conformal metal may comprise tungsten, cobalt, aluminum, or other conformal metal.

In some examples, the top electrode comprises titanium, tungsten, or a combination thereof.

In some examples, the cup-shaped carbon nanotube layer is formed by a multi-pass coating process.

Another aspect provides an integrated circuit structure including a dielectric region including a tub opening; a CNT memory cell element formed in the tub opening and including a cup-shaped bottom electrode, a cup-shaped CNT layer, and a top electrode; and an upper metal layer over the dielectric region and including a top electrode contact in contact with the top electrode.

In some examples, the dielectric region is formed over a lower metal layer including a lower interconnect element, and the CNT memory cell element is conductively connected between the lower interconnect element in the lower metal layer and the top electrode contact in the upper metal layer.

In some examples, the dielectric region is formed over a transistor including a doped source region and a doped drain region, and the cup-shaped bottom electrode of the resistive CNT cell structure is conductively coupled to a silicide region formed on the doped source region or the doped drain region of the transistor.

In some examples, the upper metal layer comprises a metal-1 interconnect layer.

In some examples, the integrated circuit structure includes a via formed in a via opening in the dielectric region, and the upper metal layer includes an interconnect element in contact with the via.

In some examples, the dielectric region is formed over a lower metal interconnect layer, and the upper metal layer comprises an upper metal interconnect layer.

In some examples, the cup-shaped carbon nanotube layer has a thickness in the range of 200 Å-500 Å.

In some examples, the conformal metal comprises tungsten, and the top electrode comprises titanium, tungsten, or a combination thereof.

In some examples, a lateral width of the tub opening is larger than a vertical height of the tub opening.

Another aspect provides an integrated circuit structure including a carbon nanotube memory cell. The carbon nanotube memory cell includes a transistor including a gate, a doped source region and a doped drain region, and a carbon nanotube memory cell element electrically coupled to the transistor. The carbon nanotube memory cell element includes a cup-shaped bottom electrode, a cup-shaped carbon nanotube layer formed in an interior opening defined by the cup-shaped bottom electrode, and a top electrode formed in an interior opening defined by the cup-shaped carbon nanotube layer.

In some embodiments, the cup-shaped bottom electrode is electrically coupled to a silicide region formed on the source region or on the drain region of the transistor.

In some embodiments, the carbon nanotube memory cell element is formed in a common via layer with at least one interconnect via or contact via.

### BRIEF DESCRIPTION OF THE DRAWINGS

Example aspects of the present disclosure are described below in conjunction with the figures, in which:

FIG. 1A is a circuit diagram of an example CNT memory cell of the prior art, and

FIG. 1B shows a structural cross-section of a CNT memory cell element of the CNT memory cell of FIG. 1A;

FIG. 2A shows an example integrated circuit structure including an example CNT memory cell element and a nearby interconnect structure formed between two metal interconnect layers, with the CNT memory cell element in an “on” (low resistance) state;

FIG. 2B shows the example integrated circuit structure of FIG. 2A, with the CNT memory cell element in an “off” (high resistance) state;

FIG. 2C shows an example integrated circuit structure including an example CNT memory cell element between two metal interconnect layers;

FIGS. 3A-3G illustrate an example process for forming the integrated circuit structure shown in FIG. 2A, including the example CNT memory cell element and interconnect structure;

FIG. 4 shows an example integrated circuit structure including the example CNT memory cell of FIGS. 2A-2B formed on a MOSFET transistor, which may define a CNT memory cell or components of a CNT memory cell; and

FIG. 5 is a flowchart of an example method for forming an example CNT memory cell element.

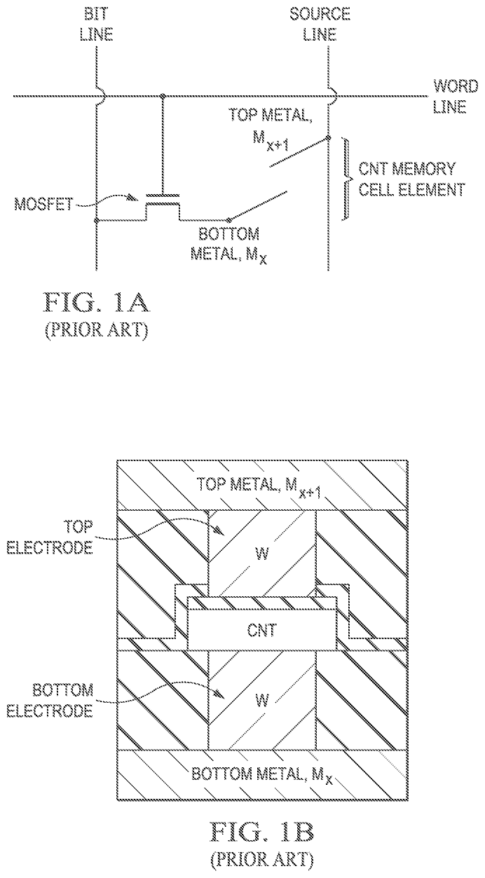

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

The present disclosure provides CNT memory cell elements and methods of forming CNT memory cell elements. A CNT memory cell element may comprise a component of a CNT memory cell, e.g., in combination with one or more transistor, as discussed herein. A CNT memory cell element may include an M/CNT/M structure formed between a lower metal layer Mₓ and an upper metal layer Mₓ₊₁. In some examples, the M/CNT/M structure may be formed in a common via layer with interconnect vias or contact vias, e.g., by deposition of tungsten or other conformal metal into respective openings in a common dielectric region. In some example, the CNT memory cell element may be formed without adding any photomask processes to a background integrated circuit fabrication process, e.g., a typical CMOS fabrication process.

As used herein, a “metal layer,” for example in the context of the lower metal layer Mₓ and upper metal layer Mₓ₊₁, may comprise any metal or metalized layer or layers, including:
(a) a metal interconnect layer, e.g., comprising copper, aluminum or other metal formed by a damascene process or deposited by a subtractive patterning process (e.g., deposition, patterning, and etching of a metal layer), or
(b) a silicided active region including a number of silicided structures (structures having a metal silicide layer formed thereon), for example a silicided source region, drain region, or polysilicon gate of a MOSFET.

For example, a CNT memory cell element may be constructed between two adjacent metal interconnect layers Mₓ and Mₓ₊₁ at any depth in an integrated circuit structure.

As another example, a CNT memory cell element may be constructed over a silicided active region, in particular on a silicon transistor having metal silicide layers formed on selected transistor components, and below a first metal interconnect layer (often referred to as Metal-1); in such an example, the silicided active region defines the lower metal layer Mₓ where x=0 (i.e., M₀) and the first metal interconnect layer (Metal-1) defines the upper metal layer Mₓ₊₁ (i.e., M₁). In some examples, the CNT memory cell element and transistor may collectively define a CNT memory cell, e.g., a 1T1C CNT memory cell, where the CNT memory cell is considered a capacitor.

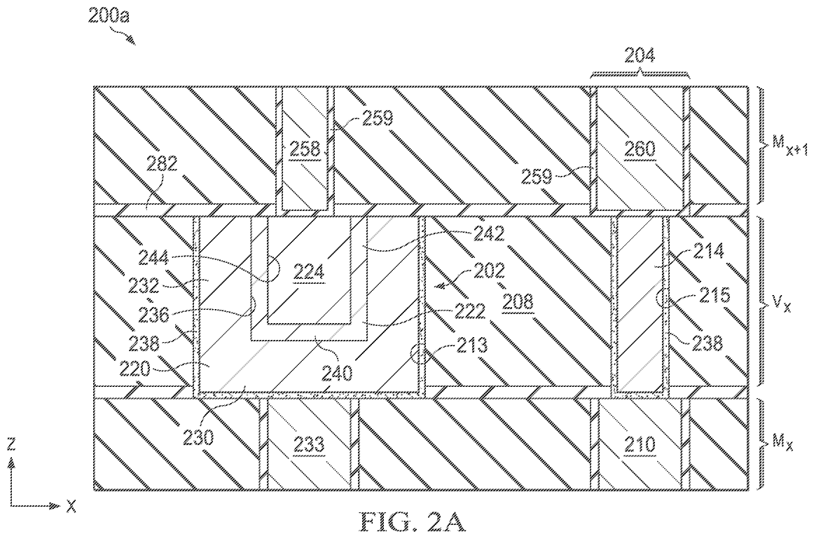

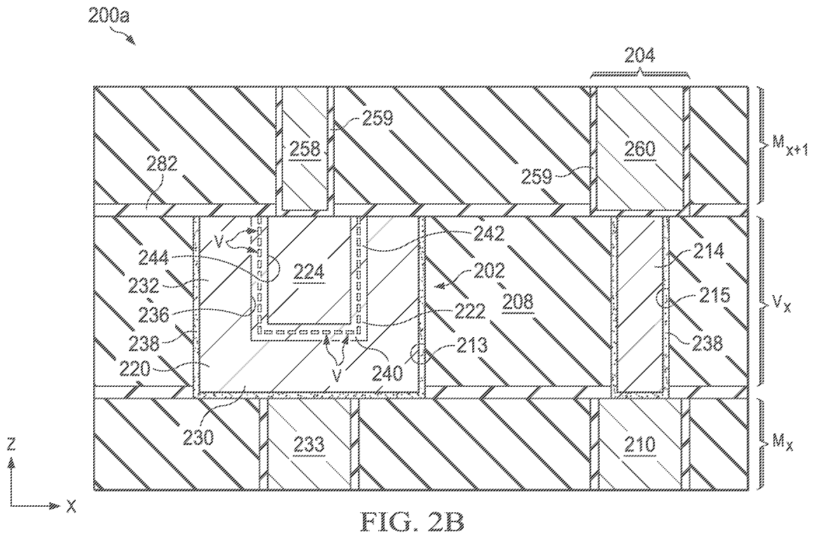

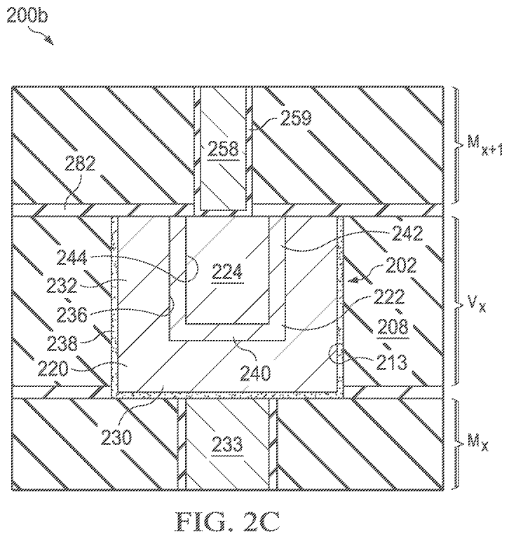

In some examples, the CNT memory cell element, in particular the M/CNT/M structure of the CNT memory cell element, may be formed concurrently with certain interconnect structures, e.g., interconnect via, separate from the CNT memory cell element. For example, a cup-shaped bottom electrode of the CNT memory cell element may be formed concurrently with interconnect vias, by deposition of a conformal metal layer, e.g., tungsten, into respective openings for the cup-shaped bottom electrode and interconnect vias. For example, FIGS. 2A-2B, 3A-3G, and 4 show example CNT memory cell elements formed concurrently with interconnect via.

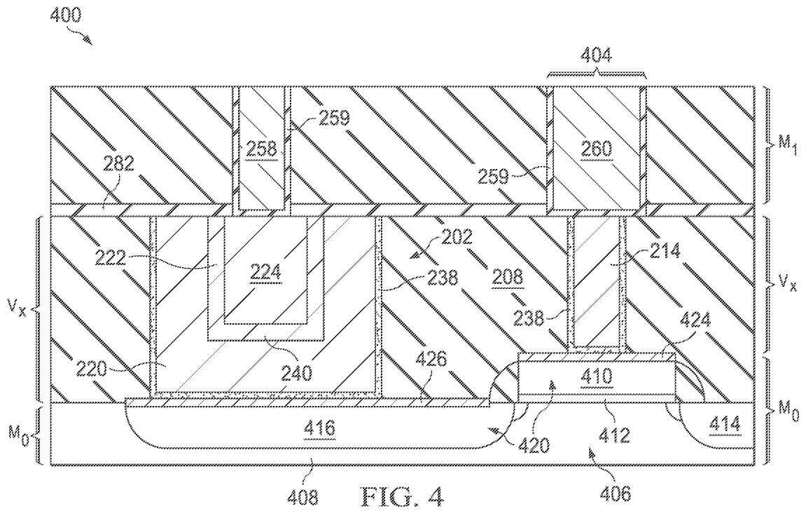

In other examples, the CNT memory cell element, in particular the M/CNT/M structure of the CNT memory cell element, may be formed distinctly (non-concurrently) from interconnect structures, e.g., interconnect vias. For example, FIG. 2C shows a CNT memory cell element having an M/CNT/M structure formed distinctly (non-concurrently) from interconnect vias. The example CNT memory cell element shown in FIG. 4 may similarly be formed distinctly (non-concurrently) from interconnect structures, e.g., interconnect vias.

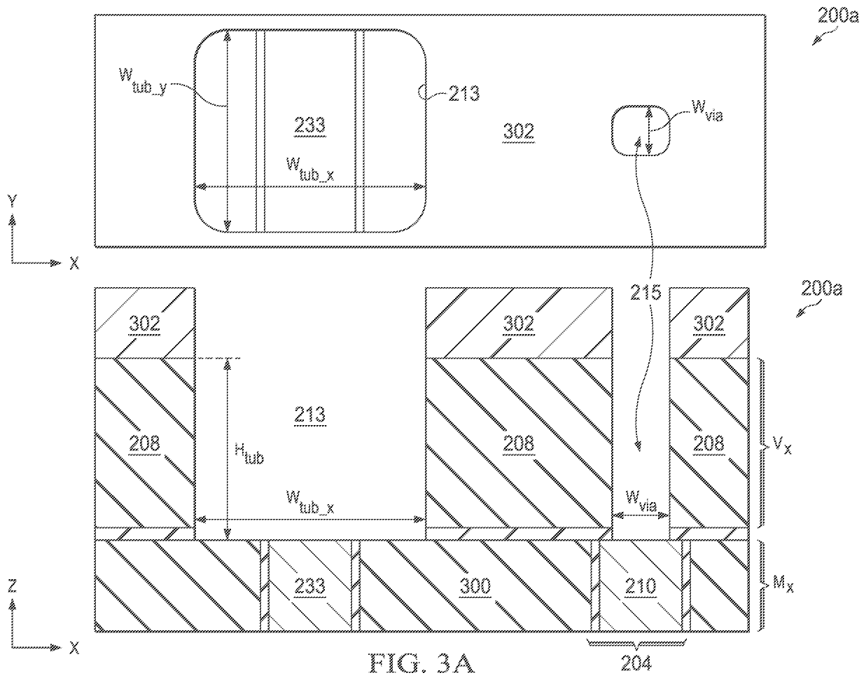

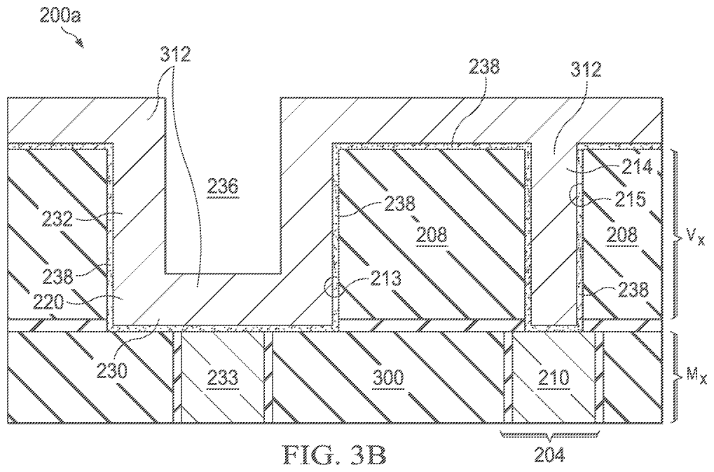

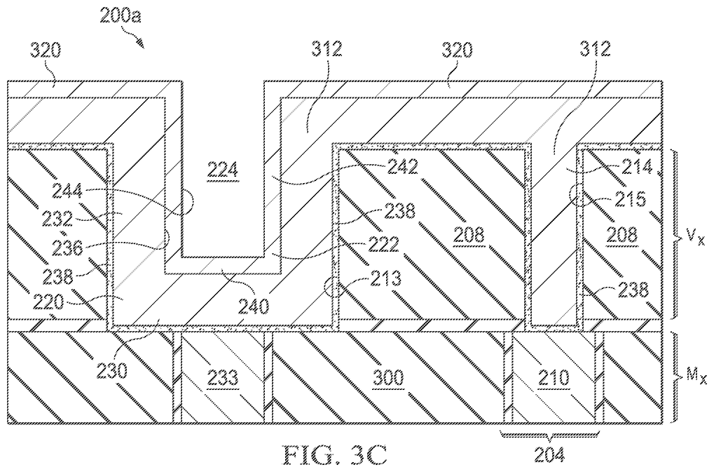

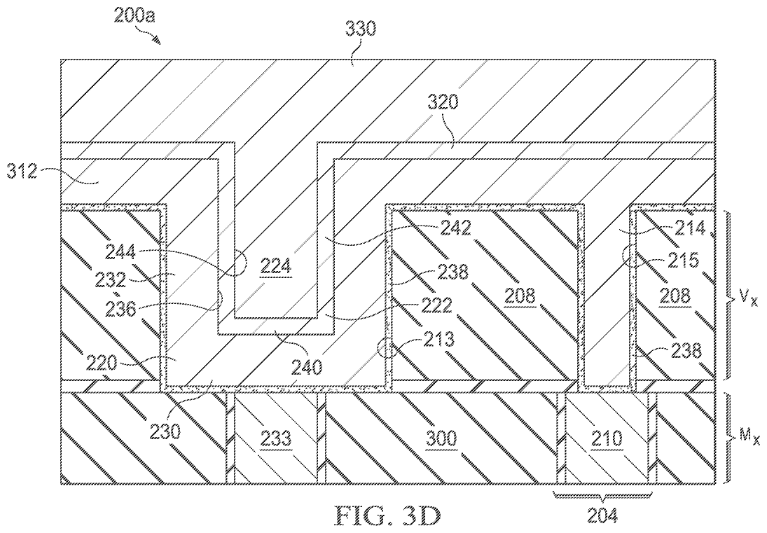

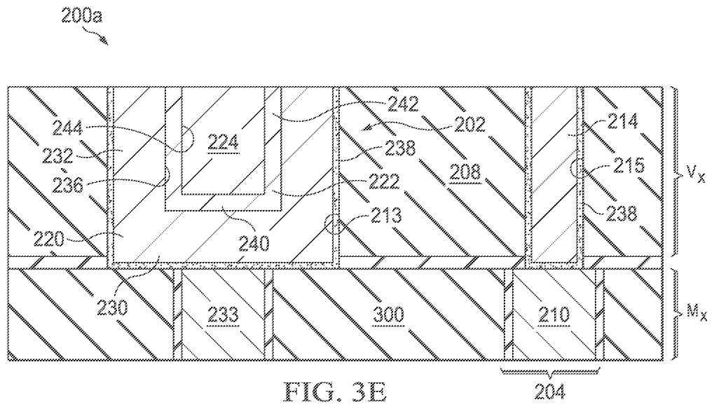

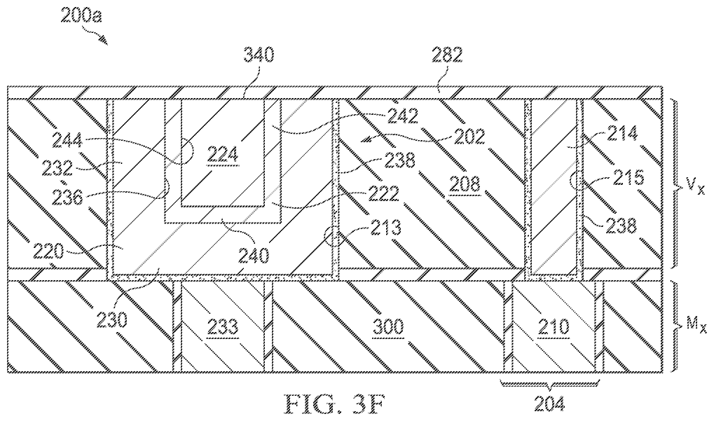

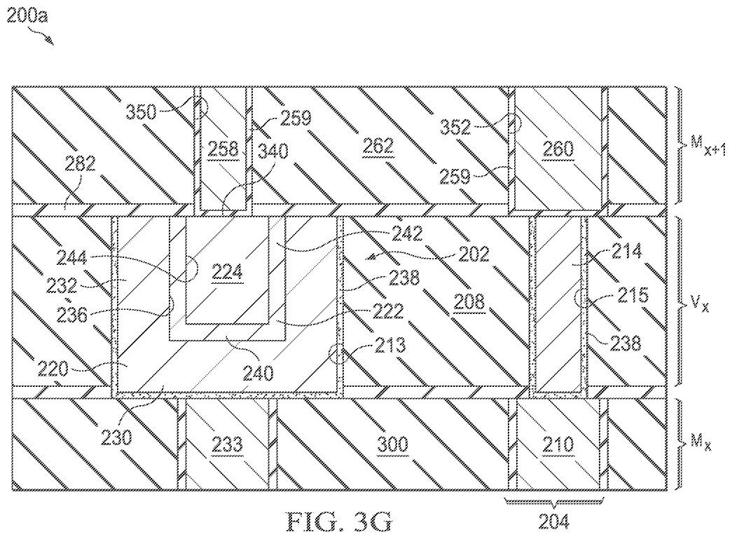

As discussed below with reference to FIGS. 3A-3G, in some examples the CNT memory cell element may be constructed without adding any mask operations to the background integrated circuit fabrication process.

FIGS. 2A and 2B show an example integrated circuit structure 200a including an example CNT memory cell element 202 and an interconnect structure 204. As discussed below, FIG. 2A shows the example CNT memory cell element 202 in an “on” state exhibiting a low overall resistance (e.g., 100 kΩ), while FIG. 2B shows the CNT memory cell element 202 in an “off” state exhibiting a high overall resistance (e.g., 1 MΩ). As noted above, the example CNT memory cell element 202 may define a component of a CNT memory cell.

Referring first to FIG. 2A, the CNT memory cell element 202 includes a three-dimensional M/CNT/M structure formed between a lower metal layer Mₓ and an upper layer Mₓ₊₁. In the example shown in FIG. 2A, FIG. 2B, and FIGS. 3A-3G, the lower metal layer Mₓ and an upper layer Mₓ₊₁ are two adjacent metal interconnect layers, such that the CNT memory cell element 202 is formed in a via layer Vₓ between the two adjacent metal interconnect layers Mₓ and Mₓ₊₁. In other examples, as shown in FIG. 4 discussed below, the CNT memory cell element 202 is formed in a via layer Vₓ between a silicided active region (including one or more silicon-based transistors including silicided structures) M₀ and a metal interconnect layer M₁ (often referred to as Metal-1). Via layer Vₓ may comprise various conductive structures formed in a dielectric region 208, e.g., an oxide region. Dielectric region 208 may be an inter-metal dielectric (IMD) region, and may be called IMD region 208, for simplicity throughout, without being limiting.

The interconnect structure 204 may include a lower interconnect element 210 formed in a lower metal layer Mₓ (for example, where x=0 for a silicided active layer as discussed above) and an upper interconnect element 260, e.g., metal-1 layer, formed in an upper metal layer Mₓ₊₁ and connected to the lower interconnect element 210 by at least one interconnect via 214 formed in via layer Vₓ by depositing a conformal metal, e.g., tungsten, cobalt or aluminum, into respective via openings 215. Each of the lower interconnect element 210 and upper interconnect element 260 may comprise a wire or other laterally elongated structure (e.g., elongated in the y-axis direction), or a discrete pad (e.g., having a square, circular, or substantially square or circular shape in the x-y plane), or any other suitable shape and structure.

The CNT memory cell element 202 comprises a metal-CNT-metal (M/CNT/M) structure formed in a tub opening 213 in the via layer Vₓ. The M/CNT/M structure of the CNT memory cell element 202 includes a cup-shaped bottom electrode 220, a cup-shaped CNT layer 222 formed on the cup-shaped bottom electrode 220, and a top electrode 224 formed in an interior opening defined by the cup-shaped CNT layer 222. The cup-shaped bottom electrode 220 includes (a) a laterally-extending bottom electrode base 230 in contact with an underlying metal interconnect element 233 and (b) multiple vertically-extending bottom electrode sidewalls 232 extending upwardly from the laterally-extending bottom electrode base 230. Metal interconnect element 233 may comprise a wire or other laterally elongated structure (e.g., elongated in the y-axis direction), or a discrete pad (e.g., having a square, circular, or substantially square or circular shape in the x-y plane), or any other suitable shape and structure.

As discussed below with reference to FIGS. 3A and 3B, the cup-shaped bottom electrode 220 may be formed concurrently with the interconnect via 214 by depositing the conformal metal, e.g., tungsten, cobalt or aluminum, into the tub opening 213 and via opening 215 in via layer Vₓ. In some example, a glue layer 238, e.g., comprising titanium nitride (TiN), is deposited in the tub opening 213 and via opening 215 prior to the conformal metal, to improve adhesion between the conformal metal and the IMD region 208.

In one example, the laterally-extending bottom electrode base 230 may have a rectangular perimeter (e.g., having a square or non-square rectangular shape) defining four lateral sides when viewed from above, with four vertically-extending bottom electrode sidewalls 232 extending upwardly from the four lateral sides of the rectangular perimeter. The cup-shaped bottom electrode 220 may include any other number of vertically-extending bottom electrode sidewalls 232 extending upwardly from the laterally-extending bottom electrode base 230.

The laterally-extending bottom electrode base 230 and vertically-extending bottom electrode sidewalls 232 define an interior opening 236 of the cup-shaped bottom electrode 220. As shown, the cup-shaped CNT layer 222 is formed in the interior opening 236 defined by the cup-shaped bottom electrode 220 and includes a laterally-extending CNT layer base 240, formed over the bottom electrode base 230, and multiple vertically-extending CNT layer sidewalls 242 extending upwardly from the laterally-extending CNT layer base 240, with each vertically-extending CNT layer sidewall 242 formed on (laterally adjacent) a respective vertically-extending bottom electrode sidewall 232.

The laterally-extending CNT layer base 240 and vertically-extending CNT layer sidewalls 242 define an interior opening 244 defined by the cup-shaped CNT layer 222. The top electrode 224 is formed inside the interior opening 244 defined by the cup-shaped CNT layer 222 and fills the interior opening 244 defined by the cup-shaped CNT layer 222. The top electrode 224 may comprise titanium nitride (TiN), tungsten (W), titanium (Ti), aluminum (Al), titanium tungsten (TiW), tantalum (Ta), tantalum nitride (TaN), copper (Cu), or a combination thereof, e.g., a combination of TiN and W, a combination of TiN and Al, or a combination of TaN, Ta, Cu.

A dielectric barrier layer 282, which may comprise a dielectric material, such as SiN or SiC, without limitation, may be formed over the top electrode 224, vertically-extending CNT layer sidewalls 242, and vertically-extending bottom electrode sidewalls 232, to thereby seal the top side of the CNT memory cell element 202. The dielectric barrier layer 282 may also extend over the interconnect via 214. The dielectric barrier layer 282 may be formed prior to formation of the upper metal layer Mₓ₊₁ to provide an etch stop for a subsequent Mₓ₊₁ trench metal etch (for forming upper interconnect element 260 and a top electrode contact 258).

The upper metal layer (Mₓ₊₁) formed over the via layer Vₓ (including interconnect via 214 and CNT memory cell element 202) includes a top electrode contact 258 in electrical contact with the top electrode 224 and an upper interconnect element 260 in electrical contact with the interconnect via 214. In some embodiments, the top electrode contact 258 and upper interconnect element 260 comprise damascene elements formed by a damascene process, e.g., using copper, tungsten, or aluminum. For example, top electrode contact 258 and upper interconnect element 260 may comprise copper damascene elements formed over a barrier layer 259, e.g., a TaN/Ta bilayer.

Top electrode contact 258 may comprise a wire or other laterally elongated structure (e.g., elongated in the y-axis direction), or a discrete pad (e.g., having a square, circular, or substantially square or circular shape in the x-y plane), or any other suitable shape and structure.

Thus, according to the example process described above, the CNT memory cell element 202, in particular the cup-shaped bottom electrode 220, may be formed concurrently with the interconnect structure 204, in particular via 214. As noted above, in other examples the CNT memory cell element 202 may be formed distinctly (non-concurrently) from interconnect structure 204 (e.g., distinct from via 214).

As mentioned above, FIG. 2A shows the CNT memory cell element 202 in an “on” state. In this state, a sufficient amount of the CNTs within the cup-shaped CNT layer 222 are touching each other to provide a low overall resistance across the cup-shaped CNT layer 222 (and as a result from the top electrode 224 to the cup-shaped bottom electrode 220, or vice versa), for example 100 kΩ.

In contrast, FIG. 2B shows the example CNT memory cell element 202 in an “off” state, wherein a sufficient amount of the CNTs within the cup-shaped CNT layer 222 are spaced apart from each other to provide a high overall resistance across the cup-shaped CNT layer 222, for example 1 MΩ. Whereas FIG. 2A represents the cup-shaped CNT layer 222 as a solid structure to indicate the CNTs are touching each other (providing a low resistance state), FIG. 2B represents the cup-shaped CNT layer 222 with voids to indicate the CNTs being spaced apart from each other (providing a high resistance state).

FIG. 2C shows an example integrated circuit structure 200b including the example CNT memory cell element 202 (in the “on” or low resistance state), wherein the CNT memory cell element 202 is formed distinctly (non-concurrently) from interconnect vias. The example CNT memory cell elements 202 shown in FIGS. 3A-3G and FIG. 4 may similarly be formed distinctly (non-concurrently) from interconnect structures, e.g., interconnect vias.

FIGS. 3A-3G illustrate an example process for forming the integrated circuit structure 200a shown in FIGS. 2A and 2B, including the example CNT memory cell element 202 and example interconnect structure 204. Those skilled in the art will recognize that the same process, without reference to interconnect structure 204, can be used to form the integrated circuit structure 200b shown in FIG. 2C, by bypassing any steps related to interconnect structure 204.

First, as shown in FIG. 3A, which includes a top view (x-y plane) and a side cross-sectional via (x-z plane) of the integrated circuit structure 200a being formed, an IMD region 208, e.g., comprising an oxide, is formed over a lower metal layer Mₓ including lower interconnect elements 210 and 233. Lower interconnect elements 210 and 233 may comprise copper elements formed by a damascene process. Each lower interconnect element 210 and 233 of lower metal layer Mₓ may comprise a wire or other laterally elongated structure (e.g., elongated in the y-axis direction), or a discrete pad (e.g., having a square, circular, or substantially square or circular shape in the x-y plane), or any other suitable shape and structure.

A photoresist layer 302 may be deposited and patterned to form photoresist openings, and the underlying IMD region 208 is etched through the photoresist openings to form tub opening 213 for the formation of CNT memory cell element 202 and one or more via openings 215 in the IMD region 208. One via opening 215 is shown in FIG. 3A. Via opening 215 may have a square, circular, or other suitable shape from a top view (x-y plane), with a width (or diameter or critical dimension (CD)) W_{Via} in both the x-direction and y-direction in the range of 0.1-0.35 μm, for example.

In contrast, the tub opening 213 may have a substantially greater width W_{tub_x} in the x-direction and/or width W_{tub_y} in the y-direction than via opening 215. The shape and dimensions of the tub opening 213 may be selected based on various parameters, e.g., for effective manufacturing of the CNT memory cell element 202 and/or for desired performance characteristics of the resulting CNT memory cell element 202. In one example, the tub opening 213 may have a square or rectangular shape in the x-y plane. In other examples, tub opening 213 may have a circular or oval shape in the x-y plane.

As noted above, a width of tub opening 213 in the x-direction (W_{tub_x}), y-direction (W_{tub_y}), or both the x-direction and y-direction (W_{tub_x} and W_{tub_y}) may be substantially larger than both the width W_{Via} of via openings 215 in the x-direction and width W_{Via} of via openings 215 in the y-direction. For example, in some examples, each width of W_{tub_x} and W_{tub_y} of tub opening 213 is at least twice as large as the width W_{Via} of via openings 215. In particular examples, each width W_{tub_x} and W_{tub_y} of tub opening 213 is at least five times, at least 10 times, at least 20 times, or at least 50 times as large as the width W_{Via} of via opening 215. Each width of tub opening 213 (W_{tub_x} and W_{tub_y}) may be sufficient to allow construction of the CNT memory cell element 202 within the tub opening 213 by a damascene process, for example allowing the construction of cup-shaped bottom electrode 220, cup-shaped CNT layer 222 formed in interior opening 236 of the cup-shaped bottom electrode 220, and top electrode 224 formed in interior opening 244 of the cup-shaped CNT layer 222. In some examples, W_{tub_x} and W_{tub_y} are each in the range of 0.5-100 μm, for example in the range of 0.5-10 μm.

Further, tub opening 213 may be formed with a height-to-width aspect ratio of less than or equal to 1 in both the x-direction and y-direction, e.g., to allow effective filling of the tub opening 213 by conformal materials and a CNT coating 320 (discussed below). For example, tub opening 213 may be formed with aspect ratios H_{tub}/W_{tub_x} and H_{tub}/W_{tub_y} each less than 1, for example in the range of 0.1 to 1. In some examples, aspect ratios H_{tub}/W_{tub_x} and H_{tub}/W_{tub_y} are each less than 0.5, for example in the range of 0.1 to 0.5, for effective filling of tub opening 213 by relevant conformal materials (e.g., tungsten, cobalt, or aluminum) and CNT coating 320. In some examples, tub opening 213 may be formed with aspect ratios H_{tub}/W_{tub_x} and H_{tub}/W_{tub_y} each less than 0.2, for example in the range of 0.1 to 0.2, or each less than 0.1.

Next, as shown in FIG. 3B, photoresist layer 302 is removed, and a glue layer 238, e.g., comprising TiN, is deposited over the IMD region 208 and extends down into the tub opening 213 and into via opening 215. The glue layer 238 may be deposited using a reactive physical vapor deposition (PVD) process or a chemical vapor deposition (CVD) process. In some examples, the glue layer 238 may have a thickness in the range of 50-500 Å.

A conformal metal layer 312 is then deposited over the glue layer 238 and extends down into the tub opening 213 and into the via opening 215. As shown, the deposited conformal metal layer 312 (a) fills interconnect via opening 215 to form the interconnect via 214 and (b) covers the interior surfaces of the tub opening 213 to form the cup-shaped bottom electrode 220 defining interior opening 236 of cup-shaped bottom electrode 220. As discussed above, the cup-shaped bottom electrode 220 includes multiple (in this example, four) vertically-extending bottom electrode sidewalls 232 extending upwardly from the laterally-extending bottom electrode cup base 230, which defines an interior opening 236 of cup-shaped bottom electrode 220. In one example, the conformal metal layer 312 comprises tungsten deposited with a thickness of 1000 Å to 5000 Å. In other examples, the conformal metal layer 312 may comprise cobalt, aluminum, or other conformal metal. The conformal metal layer 312 may be deposited by a conformal chemical vapor deposition (CVD) process or other suitable deposition process. The glue layer 238 may increase or enhance an adhesion of the conformal metal layer 312 to the interior surfaces of the tub opening 213, including vertical sidewall surfaces of tub opening 213, to facilitate the formation of the cup-shaped bottom electrode 220.

Next, as shown in FIG. 3C, a CNT coating 320 is deposited or formed over the conformal metal layer 312 and extends down into the interior opening 236 defined by the cup-shaped bottom electrode 220 to define the cup-shaped CNT layer 222 having an interior opening 244. In some examples, the CNT coating 320 has a thickness in the range of 200-500 Å. In some examples, the CNT coating 320 is formed by a multi-pass process, for example, 8 passes at 38 Å/pass for a 300 Å thick CNT film on 200 mm wafers.

Next, as shown in FIG. 3D, a top electrode layer 330 may be deposited over the CNT coating 320 and extending down into the interior opening 244 defined by the cup-shaped CNT layer 222 to form the top electrode 224. The top electrode layer 330 may comprise titanium nitride (TiN), tungsten (W), titanium (Ti), aluminum (Al), titanium tungsten (TiW), tantalum (Ta), tantalum nitride (TaN), copper (Cu), or a combination thereof, e.g., a combination of TiN and W, a combination of TiN and Al, or a combination of TaN, Ta, Cu. The top electrode layer 330 may be deposited by a PVD process and with a sufficient thickness to fill the interior opening 244 defined by the cup-shaped CNT layer 222.

Next, as shown in FIG. 3E, a chemical mechanical planarization (CMP) process may be performed to remove portions of the conformal metal layer 312, CNT coating 320, and top electrode layer 330 outside the tub opening 213 and interconnect via opening 215, leaving only the portions of cup-shaped bottom electrode 220, the cup-shaped CNT layer 222, and the top electrode 224 in the tub opening 213. The CMP process effectively planarizes the top surfaces of the cup-shaped bottom electrode 220, cup-shaped CNT layer 222, top electrode 224, via 214, and surrounding IMD region 208.

The cup-shaped bottom electrode 220, the cup-shaped CNT layer 222, and the top electrode 224 collectively define the CNT memory cell element 202. According to the process described above, the CNT memory cell element 202 is thus formed by a damascene process including (a) depositing the conformal metal layer 312, CNT coating 320, and top electrode layer 330 over the IMD region 208 and extending down into the tub opening 213, and (b) a CMP process to remove the portions of the conformal metal layer 312, CNT coating 320, and top electrode layer 330 outside (above) the tub opening 213. The CMP process is suitable for the CNT coating and for a wide variety of electrode materials, including for example W, TiN, Ti, Al, TiW, and Cu, without limitation.

Forming the CNT memory cell element 202 using such a damascene process—referred to herein as a “damascene integration”—allows the CNT memory cell element 202 to be formed without any patterning and etching processes beyond the via layer etch to form the tub opening 213 and via opening 215 (see FIG. 3A), which does not add a patterning and etch process to the background integration fabrication process (which includes a via layer etch for forming via openings). The disclosed process may be advantageous as compared with other processes for forming a CNT memory structure that require additional photoresist pattern and etch processes. Because the damascene integration involves no photoresist, no ash is needed, which avoids damage to the CNT layer.

Next, as shown in FIG. 3F, a dielectric barrier layer 282 may be deposited on the integrated circuit structure 200a. In some examples, the dielectric barrier layer 282 may comprise a dielectric material such as silicon nitride (SiN) or silicon carbide (SiC) with a thickness in the range of 300-1000 Å, for example in the range of 400-600 Å. The dielectric barrier layer 282 may seal the CNT memory cell element 202. In addition, in some examples the dielectric barrier layer 282 also acts as an etch stop layer for a damascene trench etch (e.g., Cu trench etch) during formation of overlying metal structures, as discussed below.

Next, as shown in FIG. 3G, the upper metal layer Mₓ₊₁, including the top electrode contact 258 and upper interconnect element 260, is formed above the via layer Vₓ including via 214 and CNT memory cell element 202, e.g., by a damascene process. In one example, upper metal layer Mₓ₊₁ comprises a copper interconnect layer formed by a copper damascene process.

To form the upper metal layer Mₓ₊₁, a dielectric layer 262 is first deposited over the dielectric barrier layer 282. In some examples, the dielectric layer 262 may comprise silicon oxide, FSG (FluoroSilicate Glass), OSG (Organ® Silicate Glass), or porous OSG. The dielectric layer 262 may be patterned and etched to form a top electrode contact opening 350 above the top electrode 224, and an interconnect opening 352 (e.g., trench opening) above the via 214, with the etch proceeding through dielectric barrier layer 282 through top electrode contact opening 350 and interconnect opening 352. A barrier layer (e.g., a TaN/Ta bilayer) indicated at 259 and a copper seed layer may be deposited over the dielectric layer 262 and extending down into the etched top electrode contact opening 350 and interconnect opening 352. A copper plating process may then be performed, which fills the top electrode contact opening 350 and interconnect opening 352 with copper. A copper anneal may be performed, followed by a copper CMP process to remove portions of the copper above the dielectric layer openings 350 and 352, thereby defining the top electrode contact 258 in electrical contact with the top electrode 224, and the upper interconnect element 260 in electrical contact with the via 214.

After forming the upper metal layer Mₓ₊₁ as discussed above, the process may continue to construct additional interconnect structures, e.g., by constructing additional metal layers separated by respective dielectric layers.

FIG. 4 shows an example integrated circuit structure 400 including an example CNT memory cell element 202 and an interconnect structure 404. Unlike the example shown in FIGS. 2A and 2B in which the CNT memory cell element 202 is formed between two adjacent metal interconnect layers Mₓ and Mₓ₊₁, in the example shown in FIG. 4 the CNT memory cell element 202 is formed between (a) a silicided active region M₀ (i.e., Mₓ where x=0) including silicided structures of a metal—oxide—semiconductor field-effect transistor (MOSFET) 406 and (b) a first metal interconnect layer M₁ (i.e., Mₓ₊₁ where x=0), often referred to as Metal-1.

In some examples, the CNT memory cell element 202 and MOSFET 406 may collectively define a CNT memory cell, e.g., a 1T1C memory cell, where the CNT memory cell element 202 is considered a capacitor.

As shown in FIG. 4, the silicided active region M₀ includes MOSFET 406 formed on a silicon substrate 408. The MOSFET 406 may include a polysilicon gate 410 formed over and separated from the silicon substrate 408 by a gate oxide layer 412, and a doped source region 414 and a doped drain region 416 formed in the silicon substrate 408. In this example, the polysilicon gate 410 and the doped drain region 416 comprise silicided structures 420. In particular, a metal silicide layer 424 is formed on a top surface of the polysilicon gate 410, and a metal silicide layer 426 is formed on a top surface of doped drain region 416. Metal silicide layers 424 and 426 may comprise any suitable metal silicide layer, for example titanium silicide (TiSi2), cobalt silicide (CoSi2), or nickel silicide (NiSi), having a thickness in the range of 100-300 Å or other suitable thickness. For the purposes of the present disclosure, metal silicide layers 424 and 426 define metal structures, such that the silicided active region M₀ can be considered as a metal layer.

In the example shown in FIG. 4, the CNT memory cell element 202 is formed on the metal silicide layer 426 on top of the doped drain region 416 to provide a conductive connection between the CNT memory cell element 202 and the doped drain region 416. The CNT memory cell element 202 is contacted from above by the top electrode contact 258, as discussed above. Further, the via 214 (also referred to as a contact via) is formed on the metal silicide layer 424 on top of the polysilicon gate 410 to provide conductive connection between the polysilicon gate 410 and the upper interconnect element 260. The top electrode contact 258 and upper interconnect element 260 comprise metal elements formed in the first metal interconnect layer M₁, e.g., by a damascene process. The above has been described in an example where the example CNT memory cell element 202 is formed on the metal silicide layer 426 on top of the doped drain region 416, it being understood that in other examples the CNT memory cell element 202 may be formed on a metal silicide layer on top of the doped source region 414.

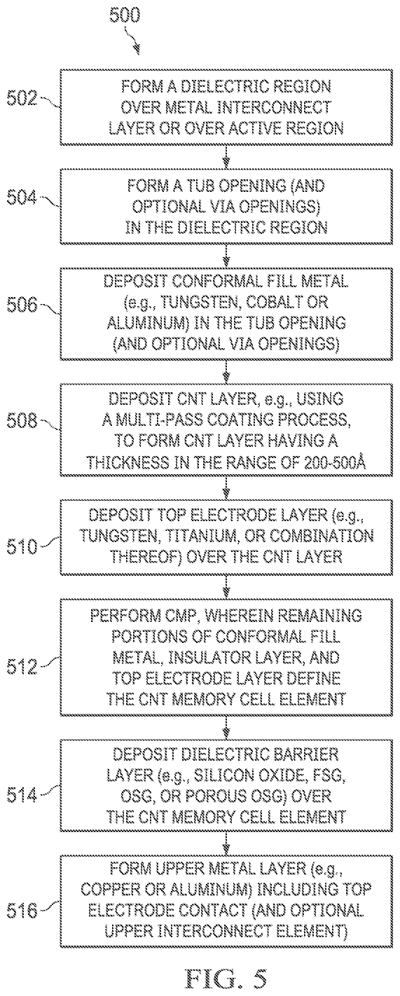

FIG. 5 is a flowchart of an example method 500 for forming the example CNT memory cell element 202 discussed above. At 502, a dielectric region is formed, e.g. dielectric region 208, over a metal interconnect layer Mₓ (for example as shown in FIGS. 2A-2C) or over a silicided active region M₀ (for example as shown in FIG. 4). At 504, a tub opening (and optionally one or more via openings) is/are formed in the dielectric region of 502 (e.g. tub opening 213 and optional via opening 215).

At 506, a conformal fill metal (e.g., tungsten, cobalt or aluminum) is deposited in the tub opening of 504 and optionally in the via openings of 504 (e.g., fill metal 312). At 508, a CNT layer is deposited, e.g., using a multi-pass coating process, to form a CNT layer having a thickness in the range of 200-500 Å. The CNT layer may be CNT layer 320. At 510, a top electrode layer (e.g., tungsten, titanium, or combination thereof) is deposited over the CNT layer of 508 (e.g. top electrode layer 320 deposited over CNT layer 320).

At 512, a CMP process is performed to remove portions of the conformal metal layer, CNT coating, and top electrode layer outside the tub opening (and optional via openings), wherein the remaining portions of the conformal metal layer, CNT coating, and top electrode layer in the tub opening define the CNT memory cell element. For example, the remaining portion of conformal metal layer 312 defines the cup-shaped bottom electrode 220, the remaining portion of CNT coating 320 defines the cup-shaped CNT layer 222, and the remaining portion of top electrode layer 330 defies the top electrode 224. In addition, the remaining portion of conformal metal layer 312 in each (optional) via opening 215 after the CMP process defines a respective via 214.

At 514, a dielectric barrier layer (e.g., comprising silicon oxide, FSG, OSG, or porous OSG, e.g. dielectric barrier layer 282) is deposited over the CNT memory cell element (and over the optional via(s)). At 516, an upper metal layer Mₓ₊₁ (e.g., copper or aluminum) is formed, including a top electrode contact (e.g., top electrode contact 258), and optionally an upper interconnect element over each via, e.g. upper interconnect element 260 over each via 214.

1. A method of forming an integrated circuit structure including a carbon nanotube memory cell element, the method comprising:
forming a tub opening in a dielectric region;
forming a cup-shaped bottom electrode in the tub opening;
forming a cup-shaped carbon nanotube layer in an interior opening defined by the cup-shaped bottom electrode;
forming a top electrode in an interior volume defined by the cup-shaped carbon nanotube layer; and
forming an upper metal layer over the dielectric region, the upper metal layer including a top electrode contact in electrical contact with the top electrode;
wherein the cup-shaped bottom electrode, the cup-shaped carbon nanotube layer, and the top electrode define the carbon nanotube memory cell element.

2. The method of claim 1, wherein the carbon nanotube memory cell element is formed by a damascene process.

3. The method of claim 1, wherein the carbon nanotube memory cell element is formed without adding any photomask processes to a background integrated circuit fabrication process.

4. The method of claim 1, comprising, prior to forming the upper metal layer over the dielectric region:
planarizing a top surface of the carbon nanotube memory cell element; and
depositing a dielectric barrier layer to cover the planarized carbon nanotube memory cell element.

5. The method of claim 4, wherein:
forming the upper metal layer over the dielectric region comprises etching an upper dielectric layer to form a top electrode contact opening for forming the top electrode contact; and
the dielectric barrier layer acts as an etch stop during the etch.

6. The method of claim 1, comprising:
concurrently forming the tub opening and a via opening in the dielectric region; and
depositing a conformal metal to concurrently form the cup-shaped bottom electrode in the tub opening and a via in the via opening.

7. The method of claim 6, wherein forming the upper metal layer over the dielectric region comprises concurrently forming the top electrode contact in electrical contact with the top electrode and an upper interconnect element in contact with the via.

8. The method of claim 6, wherein the conformal metal comprises tungsten.

9. The method of claim 1, wherein the top electrode comprises titanium, tungsten, or a combination thereof.

10. The method of claim 1, wherein forming the cup-shaped carbon nanotube layer comprises a multi-pass coating process.

11. An integrated circuit structure, comprising:
a dielectric region including a tub opening;
a carbon nanotube memory cell element formed in the tub opening and including:
a cup-shaped bottom electrode;
a cup-shaped carbon nanotube layer; and
a top electrode; and
an upper metal layer over the dielectric region and including a top electrode contact in electrical contact with the top electrode.

12. The integrated circuit structure of claim 11, wherein:
the dielectric region is formed over a lower metal layer including a lower interconnect element;
the carbon nanotube memory cell element is conductively connected between the lower interconnect element in the lower metal layer and the top electrode contact in the upper metal layer.

13. The integrated circuit structure of claim 11, wherein:
the dielectric region is formed over a transistor including a doped source region and a doped drain region;
the cup-shaped bottom electrode of the carbon nanotube memory cell element is conductively coupled to a silicide region formed on the source region or on the drain region of the transistor.

14. The integrated circuit structure of claim 13, wherein the upper metal layer comprises a metal-1 interconnect layer.

15. The integrated circuit structure claim 11, comprising a via formed in a via opening in the dielectric region; and
wherein the upper metal layer includes an interconnect element in contact with the via.

16. The integrated circuit structure of claim 11, wherein:
the dielectric region is formed over a lower metal interconnect layer; and
the upper metal layer comprises an upper metal interconnect layer.

17. The integrated circuit structure of claim 11, wherein the cup-shaped carbon nanotube layer has a thickness in the range of 200 Å-500 Å.

18. The integrated circuit structure of claim 11, wherein:
the conformal metal comprises tungsten; and
the top electrode comprises titanium, tungsten, or a combination of titanium and tungsten.

19. The integrated circuit structure of claim 11, wherein a lateral width of the tub opening is larger than a vertical height of the tub opening.

20. An integrated circuit structure, comprising:
a carbon nanotube memory cell including:
a transistor including a gate, a doped source region and a doped drain region; and
a carbon nanotube memory cell element electrically coupled to the transistor and including:
a cup-shaped bottom electrode;
a cup-shaped carbon nanotube layer formed in an interior opening defined by the cup-shaped bottom electrode; and
a top electrode formed in an interior opening defined by the cup-shaped carbon nanotube layer.

21. The integrated circuit structure of claim 20, wherein the cup-shaped bottom electrode is electrically coupled to a silicide region formed on the source region or on the drain region of the transistor.

22. The integrated circuit structure of claim 20, wherein the carbon nanotube memory cell element is formed in a common via layer with at least one interconnect via or contact via.
